(19) United States
(12) Patent Application Publication
(10) Pub. No.: US 2003/0217210 A1
(43) Pub. Date: Nov. 20, 2003

(54) Memory card having an integral battery that powers an electronic device

(76) Inventor: Frank P. Carau SR., Loveland, CO (US)

Correspondence Address: HEWLETT-PACKARD COMPANY, Intellectual Property Administration, P.O. Box 272400, Fort Collins, CO, 80527-2400, US

(21) Appl. No.: 10/147,277

(22) Filed: May 15, 2002

(51) Int. Cl. H05K 7/10; G06F 13/00

(52) U.S. Cl. 710/302

(57) ABSTRACT

A memory card has an integral battery with an energy capacity sufficient to power an electronic device. The memory card battery provides power to the electronic device while the memory card is electrically connected to the electronic device. An electronic device utilizes a memory card having an integral battery and receives power from the integral battery. A system comprising the memory card and a battery-charging unit provides power to the electronic device and recharges the memory card battery. A method of powering an electronic device comprises using the memory card battery to power the electronic device while the card is electrically connected to the device.

### TECHNICAL FIELD

The invention relates to battery-powered electronic devices. In particular, the invention relates to a battery used to power the device and a removable memory card used to store data recorded by the device.

### BACKGROUND ART

A hallmark of most battery-powered devices is their portability. In large part, portability is responsible for the popularity and market success of such devices. Portability, in turn, typically is derived from the use of a battery enclosed within the device wherein the battery is used as a primary source of operational power. Examples of popular, portable, battery-powered devices include, but are not limited to, digital cameras, personal digital assistants (PDA), and MPEG-3 (MP3) recorder/players.

In many modem electronic devices, the physical size of the device is often directly related to the physical size of the battery used to power the device. Specifically, the physical size of the battery of an electronic device typically is dictated by an energy density of the battery chemistry of the battery being employed and an expected energy consumption by the device during a ‘reasonable’ period of use. Thus, a reasonable use period often determines the size of the battery that, in turn, drives the physical size of the device.

In addition to batteries, many popular battery-powered devices employ removable memory cards for storing data generated or used by the device during operation. Each of these memory cards is capable of storing a finite number of files or a finite amount of data. The memory card may serve as a means of transporting the data from the device to an external device, such as a personal computer (PC), for further processing and/or printing. The memory card facilitates expandable data storage in the electronic device by employing multiple, spare cards, to accommodate storing as many files as may be generated during the reasonable use period of the device.

A user of such a battery-powered electronic device that has such a removable memory card often must carry both additional memory cards and additional batteries when using the device. In addition, the device is often larger, sometime much larger, than may be desirable to the user to accommodate batteries having sufficient capacity to support device operation for the reasonable period of use.

Thus, it would be advantageous to eliminate the need for carrying extra batteries along with extra removable memory cards for the device. Additionally, it would be beneficial to be able to potentially reduce the size of batteries used by battery-powered electronic devices, thereby potentially reducing the size of the device itself. Such an elimination of the need to carry extra batteries and/or such a potential ability to reduce device size would solve a problem in the area of portable electronic devices that utilize removable memory cards.

### SUMMARY OF THE INVENTION

The present invention provides a memory card having an integral battery for use with an electronic device. The integral battery of the memory card serves as a source of power for the electronic device while the card is connected to the device. In particular, the battery preferably has sufficient energy capacity to power the device while the device stores data in or ‘fills’ the memory card with data and/or accesses stored data in the memory card. More preferably and advantageously, the battery is sized to accommodate a ‘use period’ of the device corresponding to a typical time required to ‘fill’ the memory card. When the memory card is full, or the use period is up, a user of the device may replace the memory card with another memory card, thereby automatically providing both additional memory storage and a fresh, fully charged battery for the electronic device.

In one aspect of the invention, a memory card having an integral battery is provided. The integral battery of the memory card powers an electronic device that uses the memory card. The memory card comprises a memory circuit and a battery contained within a housing, and a connector. The connector is electrically interfaced to the memory circuit and the battery, and preferably, is integral to the housing.

The memory card provides data storage and/or data access for the electronic device and further, provides power to the electronic device using the memory card battery, as mentioned hereinabove. The memory card battery has sufficient energy capacity to at least provide power to the electronic device until the memory card is full. Preferably, while the memory card is connected to the electronic device, the memory card battery serves as a primary power source for the electronic device. In some embodiments, the battery may also supply power to the memory circuit to facilitate retention of data therein.

The memory card battery may be removable, replaceable or non-replaceable, and may be either rechargeable or non-rechargeable. In a preferred embodiment, the battery is rechargeable. The rechargeable battery is sized to correspond to a typical energy usage by the electronic device associated with filling the memory card with data.

Certain embodiments of the present invention have other features and/or advantages in addition to and in lieu of the features and advantages described hereinabove. These and other features and advantages of the invention are detailed below with reference to the following drawings.

### BRIEF DESCRIPTION OF THE DRAWINGS

The various features and advantages of the present invention may be more readily understood with reference to the following detailed description taken in conjunction with the accompanying drawings, where like reference numerals designate like structural elements, and in which:

FIG. 1 illustrates a block diagram of a memory card according to the present invention.

FIG. 2 illustrates a perspective view of an embodiment of a memory card of the present invention.

FIG. 3 illustrates a block diagram of an embodiment of an electronic device that utilizes a memory card having an integral battery according to the present invention.

FIG. 4 illustrates a perspective view of an embodiment of the electronic device that utilizes a memory card having an integral battery illustrated in FIG. 3.

FIG. 5 illustrates a block diagram of a system for powering an electronic device using a memory card having an integral, rechargeable battery according to the present invention.

FIG. 6 illustrates a flowchart of a method of supplying power to a portable electronic device using a memory card having an integral, rechargeable battery of the present invention.

FIG. 7 illustrates a flowchart of another method of supplying power to a portable electronic device using a memory card having an integral, rechargeable battery of the present invention.

### MODES FOR CARRYING OUT THE INVENTION

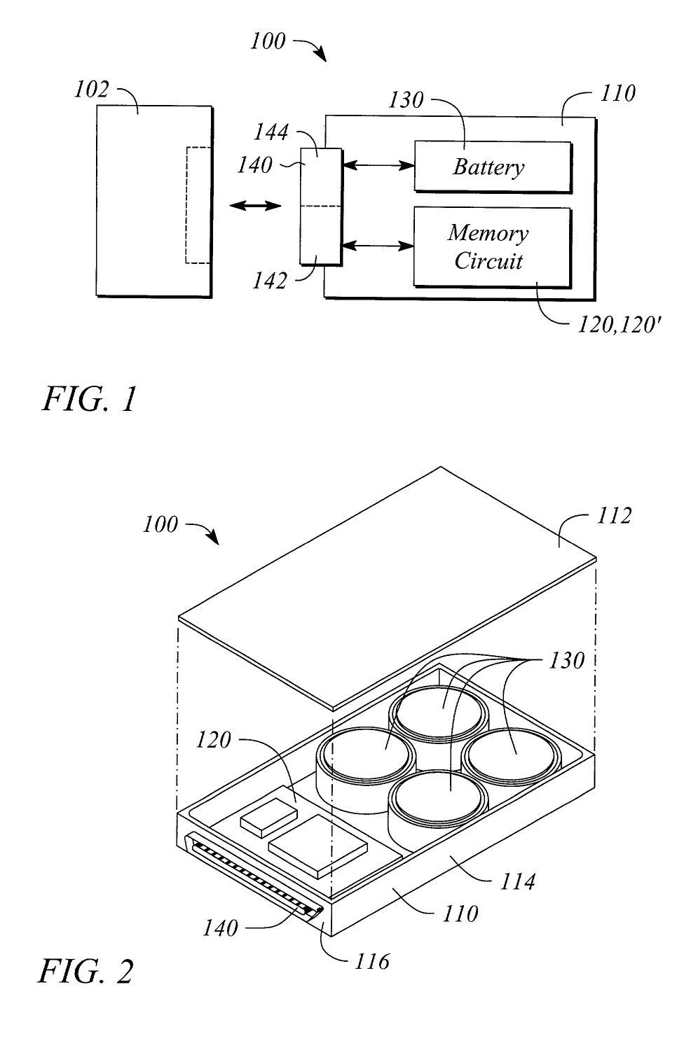

FIG. 1 illustrates a block diagram of a memory card 100 with an integral battery 130 according to the present invention. The memory card 100 is used with an electronic device 102. In particular, the integral battery 130 of the memory card 100 serves as a source of operational power for the electronic device 102. That is, the memory card 100 via the integral memory card battery 130 supplies some or all of the operational power used by the electronic device 102.

The memory card 100 comprises a computer memory or memory circuit 120, the battery 130, and a connector 140. The memory circuit 120 and the battery 130 are contained within a housing 110 and are electrically connected to the connector 140. In particular, a first portion 142 of the connector 140 is connected to the memory circuit 120 and a second portion 144 of the connector 140 is connected to the battery 130. The connector 140 provides an electrical interface to the electronic device 102.

The battery 130 is integral to the memory card 100 in that the battery 130 is a constituent or component part of the memory card 100. The integral battery 130 may be either removable or non-removable from the memory card 100. A removable battery 130 is one that is designed to be removed and replaced by a user of the memory card 100. For example, a removable battery 130 may be removed and replaced by a user when a charge or stored energy of the battery 130 is depleted. Moreover, the battery 130 may be either a rechargeable or a non-rechargeable battery type or battery chemistry. Preferably, when the battery is non-removable from the memory card 100, the battery 130 is the rechargeable battery type.

The connector 140 is any appropriate means for electrically connecting or interfacing between the memory card 100 and the electronic device 102. Specifically, the electronic device 102 stores data in and/or retrieves data from the memory circuit 120 of the memory card 100 through an electrical connection with the connector 140. Moreover, the electronic device 102 draws electrical power from the battery 130 through the connector 140. In a preferred embodiment, the battery 130 is a primary power source for the electronic device 102.

FIG. 2 illustrates an embodiment of a memory card 100 of the present invention. The connector 140 is formed into a surface 116 of and located at a first edge of the housing 110. The connector 140 is externally accessible. The memory circuit 120 and the battery 130 are located within the housing 110. The housing 110 both supports and protects the memory circuit 120 and the battery 130. For example, the housing may comprise an upper portion 112 and a lower portion 114, the lower portion 114 acting as a carrier for the battery 130 and the memory circuit 120, and the upper portion 112 acting as a lid for the lower portion 114. The housing 110 is preferably molded plastic or a combination of plastic and formed metal panels or sheets.

The electronic device 102 (not illustrated in FIG. 2) provides a means for receiving and connecting to the connector 140 of the memory card. In particular, the electronic device 102 has a port adapted to accepting the memory card 100 and a mating connector for connecting to the connector 140. For example, the port of the electronic device 102 may be a slot or opening in an end of the device that accepts the memory card 100. The slot is equipped with a mating connector that is complementary to the memory card connector 140. One skilled in the art is familiar with such ports and mating connectors on electronic devices that are adapted for accepting specialized cards and their associated connectors. All of such ports and connectors are within the scope of the present invention.

The memory circuit 120 of the memory card 100 is any appropriate means for storing data. Preferably, the memory circuit 120 comprises read/write computer memory. That is, the memory circuit 120 both can store data received from the electronic device 102 and deliver data previously stored in the memory circuit to the device 102. Typically, the computer memory is implemented as a memory integrated circuit (IC). In addition to the computer memory, the memory circuit 120 may also comprise support circuitry associated with storing and retrieving data. For example, the memory circuit 120 may include a microprocessor or a direct memory access (DMA) controller in addition to the memory IC.

In some embodiments of the memory card 100, the computer memory of the memory circuit 120 comprises flash memory, usually as a flash memory IC. Flash memory is non-volatile, read/write computer memory. The term ‘non-volatile’, as used herein, means that the memory retains data stored in the memory without an applied source of electrical bias voltage and/or electrical power. One form of flash memory is electrically erasable programmable read only memory (EEPROM). Flash memory is familiar to one skilled in the art and comes in a variety of types, all of which are within the scope of the present invention.

In other embodiments of the memory card 100, the memory circuit 120′ uses computer memory that comprises conventional random access memory (RAM) normally implemented as a RAM memory IC. As used herein, RAM is volatile read/write memory as opposed to non-volatile memory. Specifically, as used herein, RAM requires an applied power source to retain stored data. Conventionally, RAM is not used for memory cards due the need for a power source to retain stored data when the card is not connected to the device 102, or for a power source external to the device 102. Advantageously in the embodiments of the memory card 100 of the present invention that utilize the RAM-based memory circuit 120′, the integral battery 130 can be used to supply power to the RAM of the memory circuit 120′ in addition to powering the device 102. The presence of the battery 130 enables the RAM-based memory circuit 120′ to retain stored data when the memory card 100 is not connected to an external source of power and/or not connected to the device 102.

Moreover, RAM typically is less costly than an equivalently sized flash memory. In addition, RAM usually has a faster write/read time and typically provides higher data storage density than an equivalent flash memory. By taking advantage of the presence of the power source embodied in the battery 130, the memory card 100 that employs RAM-based memory circuitry 120′ advantageously may exceed the performance of and/or cost less than a conventional memory card or the embodiment of the memory card 100 that uses a flash-based memory circuit 120.

The integral battery 130 of the memory card 100 is any appropriate means for storing energy. As mentioned hereinabove, the integral battery 130 of the memory card 100 may be either rechargeable or non-rechargeable. Preferably, the battery 130 is rechargeable. The battery 130 may comprise a single cell, as illustrated in FIG. 1, or may comprise a plurality of individual cells, as illustrated in FIG. 2. Among the currently available rechargeable technologies or battery chemistries, Nickel-Metal Hydride (Ni-MH) and Lithium Ion battery chemistries are preferred for the battery 130 due to the available energy density and unit costs of these technologies. Of these, Lithium Ion batteries provide the highest energy density and therefore, are favored in potentially tight packaging conditions of the memory card 100 of the present invention. For example, a graphite Lithium Ion battery, model US103463G4, or a hard carbon Lithium Ion battery, model US103463, both of which are manufactured by Sony Corporation, Japan, may be used as the battery 130. However, bulkier battery types, such as those having conventional ‘AAA’ or ‘AA’ form factors, may also be employed with the memory card 100 of the present invention if a specialized housing 110 and a specifically adapted port of the electronic device 102 are used.

The present invention is not limited to using conventional battery chemistries and/or form factors for the energy storage means 130. In fact, the present invention is particularly useful with emerging battery technologies, especially where the technology provides sufficient energy capacity in a small space, such as on a memory card. For example, a capacitor or ultracapacitor may be used as the energy storage means 130. As such, one of ordinary skill in the art can readily select the means for storing energy appropriate for the battery 130 of the present invention.

Advantageously, various physical and/or electrical characteristics of the memory card 100 of the present invention may be based on or derived from one or more physical characteristics and/or one or more electrical characteristics of a conventional memory card. Moreover, the memory card 100 advantageously may employ a battery 130 having a conventional form factor, as opposed to a custom battery form factor. For example, the memory card 100 according to the present invention may be realized by using a commercially available, button-shaped battery cell (i.e., button cell) for the battery 130 and by mounting the battery 130 inside a convention memory card housing. In such an example realization, the memory circuit 120 may be a memory circuit of the conventional memory card and the conventional memory card connector may be used as the connector 140. According to the invention, the conventional connector may be rewired to accommodate accessing the battery 130, as well as the memory circuit. In particular, the rewired conventional connector provides access to the battery 130 for supplying operational power to the electronic device 102 that uses conventional memory cards. Using a conventional card form factor may minimize changes necessary in physical coupling and mounting hardware or ports associated with the electronic device 102 that is already adapted for using such conventional cards. Likewise, an existing interface specification for the conventional card need be changed only to reflect the addition of the battery 130 and the use of the battery 130 to power the device 102.

Specifically, conventional removable flash memory cards, such as those marketed under the names CompactFlash® Type I and Type II, Memory Stick®, SmartMedia®, and PC Cards are already in widespread use in digital cameras, PDAs and MP3 players to store data files. Advantageously, the present invention can be realized by modifying any of these conventional cards to include the integral battery 130 (and associated circuitry or interconnects) having an energy capacity sufficient to power the electronic device 102 at least while the electronic device 102 stores data on the memory circuit already present in these conventional cards. The addition of a properly sized integral battery 130 and associated circuitry, according to the invention, effectively transforms a conventional memory card into the memory card 100 of the present invention.

Of course, while the memory card 100 of the present invention advantageously can use physical and/or electrical characteristics from a conventional memory card, such as the form factor and connector thereof, the conventional electronic device 102 is not adapted to receive operational power from the memory card 100 of the present invention. Therefore, the electronic device 102 is adapted or modified to receive at least some operational power from the present memory card 100 using the integral battery 130. Moreover, some conventional electronic devices 102 may supply power to a conventional memory card. For the invention, at least the connector of such electronic devices 102 will need to be rewired accordingly to access and route the power from the memory card battery 130 to the electronic device 102. As such, a conventional power source of to the electronic device 102, after the device 102 is adapted for the memory card 100 of the present invention, is either rendered obsolete by use of the present invention or is employed by the device 102 only when the memory card 100 of the present invention is not being used.

As noted hereinabove, the conventional memory cards that have characteristics which the memory card 100 of the present invention advantageously may mimic or utilize include, but are not limited to, a Compact Flash® Type I or Compact Flash® Type II card, a Memory Stick®, a SmartMedia® Card, and a PC card. CompactFlash® is a registered trademark of Sandisk Corporation, 3270 Jay Street, Santa Clara Calif. 95054. Memory Stick® is a registered trademark of Sony Kabushiki Kaisha TA, Sony Corporation, Kitashinagawa 6-chome Shinagawa-ku, Tokyo Japan. SmartMedia® is a registered trademark of Kabushiki Kaisha Toshiba DBA, Toshiba Corporation, 72, Horikawa-cho Saiwai-ku, Kawasaki-shi, Kanagawa-ken Japan. PC Cards are credit card-size peripherals that add memory, mass storage, and input/output (I/O) capabilities in a rugged, standardized, compact form factor to computers and other similar electronic devices. The PC cards, also known as PCMCIA cards, are manufactured by a large number of memory product companies. The acronym ‘PCMCIA’ stands for the Personal Computer Memory Card International Association, a non-profit trade association and standards body that promotes PC Card technology.

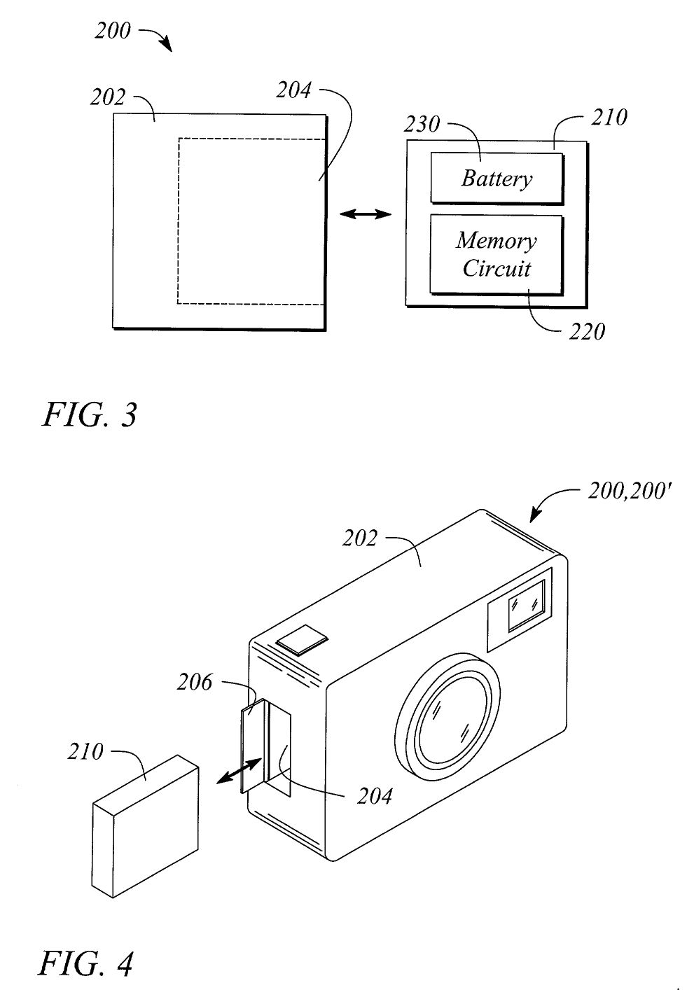

In another aspect of the invention, an electronic device is provided. The electronic device is portable or battery-powered, such that it receives at least some power from a battery. The electronic device also accepts memory cards for data storage/access. FIG. 3 illustrates a block diagram of an electronic device 200 according to the present invention. The electronic device 200 comprises a slot or port 204 in a portion of a housing 202. The port 204 is adapted for receiving a removable memory card 210 having an integral battery 230, according to the invention. The memory port 204 has a connector therein (not illustrated) that electrically interfaces with a memory card connector (also not illustrated) and that routes energy from the integral battery 230 to power the device 200.

The removable memory card 210 comprises a memory circuit 220 and the battery 230 housed in a housing, and the connector. According to the invention, the electronic device 200 receives primary operational power from the memory card battery 230 when the memory card 210 is inserted into the memory port 204. The memory card battery 230 is sized with an energy capacity to provide the operational power to the electronic device 200. In some embodiments, the electronic device 200 further comprises a power source (not illustrated) that is independent of the battery 230 power that is provided by the memory card 210. The power source typically is another battery. The electronic device 200 uses the power source when the memory card 210 of the invention is not employed in the memory port or slot 204 thereof.

FIG. 4 illustrates an embodiment of an electronic device 200 in the form of a digital camera 200′. The electronic device 200 in the form of a digital camera 200′ is exemplary and is not intended to limit the scope of the present invention. The electronic device 200 may be any battery-powered means for generating data that uses a specialized card, such as a memory card. For example, the electronic device 200 may include, but is not limited to, a digital camera, a personal digital assistant (PDA), and an MP3 player. However, electronic devices 200, such as digital cameras, are ideally suited for the invention since a primary function of the camera is to record images as data files and store the data files in memory. Moreover, digital cameras often exhibit a relatively consistent energy usage per fill period of a given memory card. This may not be the case for other battery-powered devices, such as a PDA, since many PDA functions are not associated with filling or emptying a memory card. Therefore, a digital camera 200′ is a preferred embodiment of the electronic device 200.

The digital camera 200′ embodiment illustrated in FIG. 4 has an optional door 206 to cover the memory port 204 to prevent dirt or other objects from entering the memory port 204 and damaging the connector (not illustrated) used to connect to the memory card 210. When the memory card 210 is inserted in the memory port 204, the device 200, 200′ is electrically connected to the card 210. In particular, the device 200, 200′ accesses the memory card 210 to store data, as well as retrieve previously stored data, and to obtain operating power from the memory card battery 230.

The memory card 210 comprises the memory circuit 220 with read/write computer memory. As discussed hereinabove, the computer memory may be flash memory and/or RAM. The memory card battery 230 is integral to the memory card 210, and preferably the battery 230 is rechargeable. In a preferred embodiment, the memory card 210 is the memory card 100 of the present invention, as described above. The memory card battery 230 is a primary operational power source for the electronic device 200, 200′ while the memory card 210 is electrically connected to the device 200, 200′. The battery 230 is preferably sized to accommodate at least a typical time that the electronic device 200, 200′ needs to fill the memory card 210. The removable memory card 210 is replaceable, for example when data storage capacity of the inserted memory card 210 is full, with another memory card 210 of the present invention. Advantageously, when the filled memory card 210 is replaced with the other memory card 210 of the present invention, a nearly drained memory card battery 230 in the filled memory card 210 is concomitantly replaced with a full or fresh battery 230 (i.e., fully-charged or new battery) that is in the other memory card 210. The replaced filled memory card 210 is emptied of data, and the integral battery 230 therein is recharged, such that the emptied and recharged memory card 210 is ready for reuse. Alternatively, instead of replacing the memory card 210 when it is full, the filled memory card 210 is emptied of data and the rechargeable battery 230 is recharged in situ, without removing the memory card 210 from the device 200, 200′.

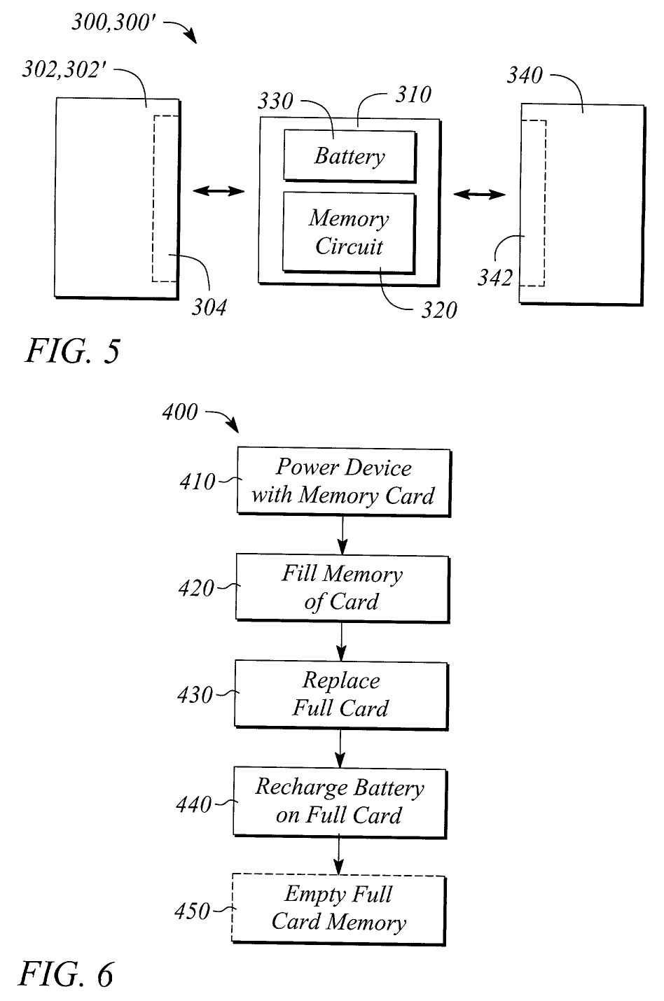

In another aspect of the invention, a system for powering an electronic device is provided. FIG. 5 illustrates a block diagram of a system 300 for powering an electronic device that uses a memory card. The system 300 comprises a memory card 310 having an integral, rechargeable battery 330 with an energy capacity to provide operational power to an electronic device 302, and a battery-charging unit 340. The battery charging unit 340 recharges the integral battery 330. The electronic device 302 derives operational power from the rechargeable battery 330 of the memory card 310 while the memory card 310 is connected to the electronic device 302. Preferably, the electronic device 302 obtains operational power from the battery 330 while the electronic device 302 fills the memory card 310 with data and/or removes/accesses stored data on the memory card 310. When the memory card 310 is filled, the data can be transferred to another medium by disconnecting the card 310 from the device 302. Moreover, the integral, rechargeable battery 330 in the memory card 310 is removed from, or preferably remains within, the memory card 310 for recharging with the battery-charging unit 340. According to the preferred embodiment, the memory card 310 is connected to the battery-charging unit 340 to recharge the integral battery 330, and more preferably, to further simultaneously empty the data stored on the memory card 310.

The electronic device 302 may be any electronic device that utilizes a removable memory card. Further, the electronic device 302 is any electronic device that obtains at least some power from a battery, such as a portable electronic device. Examples of electronic devices 302 include, but are not limited to, a digital camera, a PDA, and an MP3 player. In a preferred embodiment, the electronic device 302 is the electronic device 200, 200′, as described above. The memory card 310 comprises read/write computer memory 320, as well as the integral, rechargeable battery 330. The memory 320 accepts and stores data from the electronic device 302, as well as provides previously stored data to the electronic device 302. For example, if the electronic device 302 is a digital camera, the data may be files containing images recorded by the camera. The memory card 310 is preferably the memory card 100 described hereinabove.

The electronic device 302 has a memory port 304 and a connector associated with the port that are adapted to receive and electrically connect to the memory card 310 via a compatible or complementary connector on the memory card 310. The memory card connector provides an external electrical interface to both the battery 330 and the computer memory 320 that are internal to the memory card 310.

The charging unit 340 comprises a port 342, a connector associated with the port 342, and a battery charging circuit (not illustrated). In general, the battery charging circuit is specific to a type or chemistry of the rechargeable battery 330 and may be implemented using any one of a number of well-known circuits for charging rechargeable batteries. For example, the battery charging circuit may comprise a MAX1647 Chemistry Independent Battery Charger integrated circuit (IC) manufactured by Maxim Integrated Products, Sunnyvale, Calif. The MAX1647 provides digitally programmable power and current control for charging batteries of a various different chemistries. In addition, the battery charging circuit 340 may further comprise an AC-DC converter that converts an AC source of power into DC power for use by the battery charging IC.

The port 342 and associated connector are adapted to receive and electrically connect to the memory card 310. The charging unit 340 connector is complementary to the memory card 310 connector. The memory card 310 connector that connects to the battery charging unit 340 may be the same as, or may be a different connector on the memory card 310 than, the connector used to connect the card 310 to the electronic device 302. The charging unit 340 recharges the battery 330 in the memory card 310 when the card 310 is connected to the charging unit 340.

In a preferred embodiment, the charging unit 340 further comprises a memory download interface to download data stored on the memory card 310. Advantageously in the preferred embodiment, the memory card 310 can be emptied while the battery 330 is being charged. In particular, the charging unit 340 may be connected to an external personal computer (PC) or to a network access port of a network. While the battery 330 is being recharged, the charging unit 340 may transfer the data stored in the card 310 to the PC or network. Similarly, data may be uploaded from the PC and/or network to the memory card 310 by the charging unit 330 of the preferred embodiment.

Consider, for example, the electronic device 302 in the form of a digital camera 302′. A user of the camera 302′ places an empty memory card 310 having a fully charged battery 330 into a memory card port 304 of the camera 302′. The user then records a series of images using the camera 302′. The images are recorded as image files and are stored in the memory 320 of the memory card 310. At least while the user records the images with the camera 302′, the camera 302′ obtains power from the battery 330 of the memory card 310. When the memory card 310 is full, the user removes the full card 310 from the camera 302′ and replaces the full memory card 310 with another memory card 310 of the present invention. As used herein, a ‘full’ or ‘filled’ memory card 100, 210, 310 is a memory card that has reached its data storage capacity. In other words, the full memory card cannot accept and store any more data beyond that of its storage capacity. For the digital camera 302′ example, the full memory card 310 can accept and store no additional image files. However, the memory card 100, 210, 310 need not be full to be replaced or removed from the electronic device 102, 200, 200′, 302, 302′ for the purposes of the invention.

According to the preferred embodiment, when the user wants to download the image files recorded on the memory card 310, the user places the removed card 310 in the charging unit 340. The charging unit 340 in this example is connected to a PC. The user employs the PC to contact the charging unit 340 and access the previously recorded image files on the removed memory card 310. The files are downloaded and the memory 320 is thus emptied. Advantageously, when the user places the memory card 310 in the charging unit 340, the charging unit 340 also begins to recharge the battery 330. Thus, while the user is downloading the image files, the battery 330 is being recharged and readied for reuse in powering the device 302′.

In some cases, the battery 330 has a capacity equal to or slightly greater than that necessary to power the device 302, 302′ for a period of time necessary to fill the memory card 310. Preferably, the battery 330 has a capacity that exceeds a minimum average time to fill the memory card 310. For example, a user of the camera 302′ embodiment may record more images than the user actually decides to store on the memory card 310. If a user of the camera 302′ in this example typically stores on the card 310 approximately half of all images captured or recorded by the camera 302′, preferably the battery 330 is sized to have an energy capacity that is twice that necessary to power the camera 302′ while the camera records and stores a full memory card 310 of images as image files. One skilled in the art can readily size the battery 330 for a given electronic device 302, 302′ and known or expected patterns of use without undue experimentation.

For example, consider the memory card 100 for use with the exemplary digital camera 302′, the memory card 100 having 16 megabytes (MB) of memory 120. Such an exemplary digital camera 302′ may store approximately 16 images in 16 MB of computer memory. However, a user of the digital camera 302′ typically may capture an average of two images for each image actually stored in the memory card 100. Moreover, assume that the exemplary digital camera 302′ consumes approximately 0.17 Watt-hours (W-H) of energy for each image either captured or captured and stored in memory. Thus, to fill the example memory card 100 using the example camera 302′ and assuming that a total of thirty-two images are captured and sixteen are stored, the camera 302′ requires approximately 5.47 W-H of energy.

It is known that Lithium Ion batteries, such as the model US103463G4 manufactured by Sony mentioned hereinabove, are capable of providing energy storage densities on the order of 400 W-H/liter. Thus, a memory card battery 130 based on the Sony Lithium Ion technology and having a volume of approximately 13.68 ml or 13,680 mm³ can supply enough energy to fill the memory card 100 for the example.

Continuing with the example, consider that a standard CompactFlash® Type I card has physical dimensions of approximately 36 mm by 42 mm by 3 mm equating to a volume of approximately 4,536 mm³. Assuming that a memory circuit and a connector of the CompactFlash® Type I card take up approximately one-third of the volume of the Type I card, a volume needed to accommodate the connector 140 and the memory 120 of the memory card 100 of this example may be approximately 1,512 mm³. As a result, a total volume of the connector 140, the memory 120 and the battery 130 is approximately 15,192 mm³ for the example memory card 100. The memory card 100 having dimensions 36 mm by 42 mm by 11 mm, for example, provides a volume of 16,632 mm³ or approximately enough room to house the memory 120, the battery 130, and the connector 140 and leave sufficient additional volume to account for a housing. The memory card 100, based on the CompactFlash® form factor, in this example, would be approximately four times as thick as a Type I card or two times as thick as a Type II card.

In another embodiment, the system 300′ further comprises the electronic device 302, and the memory card 310 maybe emptied of the data stored therein while still connected to the electronic device 302. Similarly, the battery 330 may be recharged while the memory card 310 is still connected to the electronic device 302. In such an embodiment, the battery-charging unit 340 is essentially built into the electronic device 302. Thus, a data input/output (I/O) port of the device 302 may enable data stored in the filled memory card 310 to be downloaded while the memory card is connected to the device 302. Similarly, a power port on the device 302 may provide for recharging the memory card battery 330 while the memory card 310 is connected to the device 302. A combination of a built-in battery-charging unit 340 and an external battery-charging unit 340 may also be employed with some embodiments of the system 300, 300′ for powering an electronic device 302.

In another aspect of the invention, a method of supplying power to an electronic device is provided. FIG. 6 illustrates a flowchart of a method 400 of supplying power to a portable electronic device. According to the method 400 of the present invention, the portable electronic device derives some or all of its operating power from a battery. Further, the portable electronic device accepts memory cards. The method 400 comprises powering 410 the electronic device with a memory card. The memory card comprises an integral battery. The memory card powers the electronic device with the integral battery while the memory card is electrically connected to the electronic device. Preferably, the electronic device is powered 410 while filling the memory card with data from the device.

The device is powered 410 with a first memory card. The first memory card comprises an integral battery having an energy capacity sufficient to power the device when the first memory card is inserted in the device. Depending on the embodiment, the method 400 further comprises filling 420 the first memory card with data produced by the device. The battery of the first memory card powers the device during filling 420 of the memory card. Filling 420 may comprise either partially or completely filing 420 the first memory card. The method 400 further comprises replacing 430 the first memory card when it is filled, or when usage of the memory card is completed, with a second memory card. In general, replacing 430 the first memory card with the second memory card provides the device with both the second memory card and a fresh battery. The fresh battery is either a new (i.e., fully-charged or never used) battery or a recharged battery.

The second memory card may be an empty or unfilled card (i.e., having no data stored thereon) or may be a partially filled or completely filled second memory card. Where the second memory card is partially or completely filled, the second memory card replaces the first memory card for the purpose of either or both accessing the data stored on the second memory card and storing additional data on the partially filled second memory card. Where a partially filled second memory card is used to replace 430 the first memory card, the battery in the partially filled second memory card may or may not be fresh or fully recharged, according to the invention. However, the battery in the partially filled second memory card has at least sufficient remaining energy to power the device while the remaining memory capacity of the partially filled second memory card is then filled.

The method 400 further comprises recharging 440 the battery of the first memory card. During recharge, the battery may be cycled to insure that a maximum operational life of the battery is achieved. In a preferred embodiment, the method 400 optionally further comprises emptying 450 the first memory card of data while the battery is recharged 440. Emptying 450 preferably comprises transferring the data stored on the first memory card to an external device, such as a PC, or to a network, such as the Internet. Recharging 440 and emptying 450 produce a first memory card having a battery that is ready for reuse in the device. In particular, memory of the reusable first memory card is empty and able to accept a full amount of data from the device as a result of emptying 450, and the battery is recharged and has a full charge capacity for powering the device as a result of recharging 440. Preferably, recharging 440 and emptying 450 are performed simultaneously.

In some embodiments, replacing 430 the first memory card may be omitted or skipped. In particular, replacing 430 the first memory card may be omitted when the device provides for recharging 440 the battery and/or emptying 450 the memory card memory while the first memory card is still inserted in the device. In such a situation, the second memory card is not required. The first memory card powers 410 the device while the card memory is filled 420. The battery then may be recharged 440 in situ by employing a built-in battery charger of the device, for example. Similarly, the card memory may be emptied in situ using a data I/O port on the device, for example.

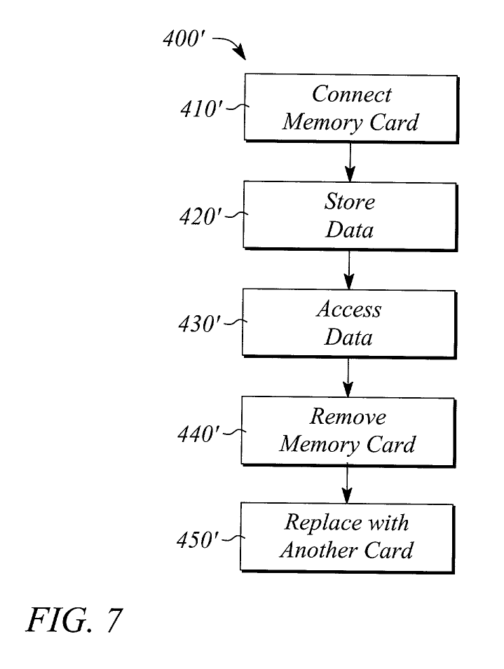

In another embodiment illustrated in FIG. 7, the method 400′ of supplying power to an electronic device comprises powering the electronic device with a memory card having an integral battery, wherein the integral memory card battery has an energy capacity sufficient to provide operational power to the electronic device. The electronic device is powered by connecting 410′ a memory card to a memory port of the electronic device. The memory card of the method 400′ comprises the integral battery. The memory card integral battery supplies power to the device while the memory card is connected to the memory port. In some embodiments, the method 400′ further comprises storing 420′ data in and/or accessing 430′ data from the connected memory card with the device. The electronic device is supplied power from the integral battery during storing 420′ and/or accessing 430′ data. In these embodiments, the method 400′ further comprises empting data stored in the memory card and recharging the integral battery. In some of these embodiments, emptying stored data and recharging the integral battery comprises removing 440′ the memory card when a storage capacity of the card is full or usage of the memory card is no longer desired. Further in these embodiments, the method still further comprises replacing 450′ a removed memory card with ‘another’ memory card that comprises an integral battery. The ‘other’ memory card may be different card with an integral battery or the removed memory card after transferring or empting the data stored therein and recharging or replacing the integral battery. In others of these embodiments, emptying stored data and recharging the integral battery comprises connecting the electronic device or the memory card to an interface unit to download the stored data and recharge the integral battery while the memory card is still connected to the electronic device.

The present invention advantageously enables electronic devices that utilize memory cards to be smaller in size than would otherwise be practical. In particular, by sizing the battery according to the energy necessary to accommodate the fill time of the memory card instead of an otherwise reasonable use period of the device, the battery is potentially made much smaller than a conventional battery for the device. As such, the device may be made smaller, as well. Moreover, combining the battery with the memory card provides a fresh or fully charged battery with each memory card that is inserted into the device, thereby reducing the need for a user of the device to carry extra batteries along with extra memory cards. Additionally, if the memory card battery is rechargeable and is automatically recharged each time data in the card is downloaded to empty the card, the battery of an empty card will always be filly charged when a user inserts the card into the device. Thus according to the invention, the user can count on having a battery with sufficient energy to fill each memory card.

Thus, there has been described a memory card comprising an integral battery, the battery having an energy capacity sufficient to power an electronic device, the electronic device using the memory card. Further described are an electronic device that uses the memory card for power, a system for powering the electronic device, and a method of powering an electronic device that uses a memory card having an integral battery. It should be understood that the above-described embodiments are merely illustrative of the some of the many specific embodiments that represent the principles of the present invention. Clearly, those skilled in the art can readily devise numerous other arrangements without departing from the scope of the present invention.

What is claimed is:

1. A memory card that stores data from an electronic device comprising:
a memory circuit where the data is stored;
a battery integral to the memory card having an energy capacity to power the electronic device;
a housing that encloses the memory circuit and the battery; and
a connector that electrically interfaces the memory circuit and the battery through the housing, the connector providing electrical connection with the electronic device, the integral battery powering the electronic device while electrically connected to the electronic device.

2. The memory card of claim 1, wherein the battery powers the electronic device while the electronic device one or both stores and accesses data on the memory card.

3. The memory card of claim 1, wherein the integral battery is non-removable.

4. The memory card of claim 3, wherein the battery is a rechargeable-type battery, the connector providing access to the battery to recharge the battery.

5. The memory card of claim 1, wherein the battery is a rechargeable-type battery.

6. The memory card of claim 1, wherein the battery is replaceable, the replaceable battery being removable from the housing.

7. The memory card of claim 6, wherein the battery is either a rechargeable-type battery or a nonrechargeable-type battery.

8. The memory card of claim 1, wherein the memory card is reusable, the connector providing access to the memory circuit to download stored data from the reusable memory card.

9. The memory card of claim 8, wherein the battery is rechargeable, the connector further providing access to the battery to recharge the battery.

10. The memory card of claim 9, wherein the connector provides simultaneous access to the memory circuit and the battery to download and recharge, respectively.

11. The memory card of claim 1, wherein the battery powers the electronic device at least for a fill period, the fill period being a period of time to fill the memory circuit with data to a maximum data storage capacity.

12. The memory card of claim 1, wherein the memory circuit comprises one or both of flash memory and random access memory (RAM), the battery providing energy to further power the RAM.

13. A portable electronic device comprising:
a memory port having a connector; the port being adapted to receive a memory card, the memory card comprising a memory circuit and an integral battery enclosed in a housing, and a connector, the memory card connector electrically interfacing the memory circuit and the battery in the housing to the memory port connector, the memory card battery having an energy capacity to provide operational power to the electronic device,
wherein the memory port connector transfers energy from the memory card battery to the electronic device to power the electronic device while the memory card is electrically interfaced to the memory port.

14. The portable electronic device of claim 13, wherein the memory card battery powers the electronic device while the electronic device accesses the memory circuit of the memory card.

15. The portable electronic device of claim 13, wherein the memory card battery powers the electronic device while the electronic device stores data on the memory circuit of the memory card.

16. The portable electronic device of claim 13, wherein the memory card battery powers the electronic device until a data storage capacity of the memory circuit is full.

17. The portable electronic device of claim 13, wherein the memory card battery provides all of the power that the electronic device needs to operate.

18. The portable electronic device of claim 13, further comprising the memory card.

19. The portable electronic device of claim 18, wherein the memory card battery is one of a rechargeable-type battery and a nonrechargeable-type battery.

20. The portable electronic device of claim 19, further comprising:
a data input/output (I/O) port, the I/O port enabling data stored in the memory circuit of the memory card to be downloaded while the memory card is electrically connected to the memory port of the device; and
a power port, the power port providing for recharging the memory card battery while the memory card is electrically connected to the memory port of the device.

21. The portable electronic device of claim 13, further comprising:
a data input/output (I/O) port, the I/O port enabling data stored in the memory circuit of the memory card to be downloaded while the memory card is electrically connected to the memory port of the device; and
a power port, the power port providing for recharging the memory card battery while the memory card is electrically connected to the memory port of the device

22. The portable electronic device of claim 13, further comprising a power source that is independent of the memory card battery, the power source providing power to the device when the memory card is electrically disconnected from the memory port.

23. The portable electronic device of claim 13, wherein the device is selected from a digital camera, a personal digital assistant (PDA), and MPEG-3 (MP3) player.

24. A system for powering an electronic device comprising:
a memory card that comprises a memory circuit and an integral, rechargeable battery enclosed in a housing, and a connector that provides respective electrical interfaces to the memory circuit and the rechargeable battery, the memory card connector being complementary to a connector of the electronic device, the rechargeable battery having an energy capacity to power the electronic device; and
a battery charging unit comprising charging circuitry that recharges the memory card battery when the memory card is electrically connected to the charging unit,
wherein the memory card battery powers the electronic device while the memory card and electronic device are electrically connected.

25. The system of claim 24, wherein the battery charging unit further comprises a charging unit port and a charging unit connector, the unit connector being associated with the unit port, the unit connector being complementary to the memory card connector for electrical connection, the unit port being sized to receive at least a portion of the memory card such that electrical connection is achieved.

26. The system of claim 24, wherein the battery charging unit further comprises a memory download interface to download data stored on the memory circuit while the charging unit recharges the memory card battery.

27. The system of claim 24, further comprising the electronic device, the electronic device comprising a memory port, the electronic device connector being associated with the memory port, the memory port being adapted to receive at least a portion of the memory card with the integral battery for electrical connection.

28. The system of claim 27, wherein the battery charging unit is built into the electronic device.

29. The system of claim 28, wherein electronic device further comprises a data input/output (I/O) port, and a power port, such that while the memory card is electrically connected to the electronic device, the data I/O port provides for downloading data stored on the memory card and the power port provides for recharging the integral memory card battery.

30. The system of claim 24, wherein the rechargeable battery is either removable or non-removable from the memory card.

31. The system of claim 24, wherein the rechargeable battery provides power to the electronic device while the electronic device accesses the memory circuit.

32. The system of claim 24, wherein the rechargeable battery provides power to the electronic device at least until a data storage capacity of the memory circuit is full.

33. The system of claim 24, wherein the rechargeable battery further provides power to the memory circuit.

34. The system of claim 24, wherein the memory circuit is selected from one or both of flash memory and random access memory (RAM).

35. The system of claim 24, wherein the electronic device is selected from a digital camera, a personal digital assistant, and an MPEG-3 (MP3) recorder/player.

36. A method of supplying power to an electronic device comprising:
powering the electronic device with a memory card, the memory card comprising a memory circuit and an integral battery housed in a housing, and a connector that electrically connects the memory circuit and the integral battery of the memory card to the electronic device, the integral battery having an energy capacity to power the electronic device, the integral battery providing power to the electronic device when electrically connected.

37. The method of supplying power of claim 36, further comprising:
accessing the memory circuit using the powered electronic device, the memory card battery providing power to the electronic device while the device accesses the memory circuit.

38. The method of supplying power of claim 36, further comprising:
recharging the memory card battery in the memory card.

39. The method of supplying power of claim 38, further comprising:
downloading the data stored in the memory card.

40. The method of supplying power of claim 39, wherein recharging and downloading are performed simultaneously.

41. The method of supplying power of claim 39, further comprising:
removing the memory card from the electronic device prior to recharging the memory card battery and prior to downloading the data stored in the memory card.

42. The method of supplying power of claim 36, further comprising:
replacing the memory card with another memory card that comprises a memory card battery having an energy capacity to power the electronic device.

43. A portable electronic device comprising:
means for receiving and electrically connecting to a memory card, the memory card having an integral battery, the integral battery of the memory card having an energy capacity to provide operational power to the electronic device; and
means for using energy from the memory card battery for power, such that while the memory card is electrically connected to the means for receiving, the memory card battery powers the electronic device.

44. The portable electronic device of claim 43, wherein the memory card battery is a rechargeable-type battery, the memory card further having means for accessing the memory card battery to recharge the battery.

45. The portable electronic device of claim 43, wherein the memory card battery is removable from the memory card, the memory card battery being one of a rechargeable-type battery and a nonrechargeable-type battery.

46. The electronic device of claim 43, wherein the memory card further having means for storing data, and means for accessing the data storing means to download stored data from the electronic device, or to upload stored data to the electronic device, and wherein the memory card further has means for accessing the memory card battery to recharge the battery.

47. The electronic device of claim 46, wherein the means for accessing the data storing means and the means for accessing the memory card battery simultaneously download or upload data and recharge the battery, respectively.

48. A system for powering a portable electronic device that generates data to be stored comprising:
a memory card that comprises means for storing data and means for storing energy enclosed in a housing, and means for electrically connecting the data storage means and the energy storage means to the portable electronic device, the energy storage means having an energy capacity to power the electronic device; and
means for charging the energy storage means when the memory card is electrically connected to the charging means,
wherein the energy storage means powers the portable electronic device while the memory card and the portable electronic device are electrically connected.

49. The system of claim 48, wherein the charging means comprises means for receiving and electrically connecting to the memory card, the means for receiving being sized to receive at least a portion of the memory card, such that electrical connection is achieved.

50. The system of claim 49, wherein the charging means further comprises means for downloading data stored in the data storage means while the charging means recharges the energy storage means.

51. The system of claim 48, wherein the energy storage means is either removable or non-removable from the memory card.

52. The system of claim 48, wherein the energy storage means provides power to the electronic device while the electronic device accesses the data storage means.

53. The system of claim 48, wherein the energy storage means provides power to the electronic device at least until a data storage capacity of the data storage means is full.

54. The system of claim 48, wherein the energy storage means further provides power to the data storage means.

55. The system of claim 48, further comprising a portable means for generating data, the portable data generating means comprising means for receiving the memory card for electrical connection, such that when the portable data generating means is electrically connected to the memory card, the energy storage means provides operational power to the portable data generating means at least while the portable data generating means stores generated data in the data storage means of the memory card.

56. The system of claim 55, wherein the charging means is built into the portable data generating means.

57. The system of claim 56, wherein the portable data generating means further comprises means for downloading data stored in the data storage means, and means for providing power to the charging means, such that while the memory card is electrically connected to the portable data generating means, the data stored in the data storage means is downloaded and the charging means provides energy to the energy storage means.

58. The system of claim 55, wherein the portable data generating means is selected from a digital camera, a personal digital assistant, and an MPEG-3 (MP3) recorder/player.

59. A memory card that stores data from an electronic device comprising:
means for storing data;
means for storing energy having an energy capacity to power the electronic device, the data storing means and the energy storing means being integral to the memory card; and
means for electrically connecting the data storing means and the energy storing means to the electronic device, the energy storing means powering the electronic device while electrically connected to the electronic device.

60. The memory card of claim 59, wherein the energy storing means powers the electronic device at least while the electronic device fills the data storing means with data to a maximum data storage capacity.
